(19) United States
(12) Patent Application Publication
(10) Pub. No.: US 2014/0320161 A1
(43) Pub. Date: Oct. 30, 2014

(54) TESTING SYSTEM AND METHOD FOR DC-TO-DC BUCK CONVERTER CIRCUIT

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: WEI-HUA CAO, Shenzhen (CN); FEN-FEN CHEN, Shenzhen (CN); QING LI, Shenzhen (CN); HAO HU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/151,026

(22) Filed: Jan. 9, 2014

(30) Foreign Application Priority Data
Apr. 30, 2013 (CN) 2013101555116

(51) Int. Cl. G01R 31/28

(52) U.S. Cl. CPC G01R 31/282
USPC 324/764.01

(57) ABSTRACT

A testing system for a DC-to-DC buck converter circuit includes a multi-meter connected to the DC-to-DC buck converter circuit, an oscilloscope, and a control device. The control device is connected to the multi-meter and the oscilloscope and is configured to adjust the multi-meter and the oscilloscope, and gather data and waves measured by the multi-meter and the oscilloscope. The control device generates a test report according to the data and waves measured by the multi-meter and the oscilloscope. The present disclosure further discloses a testing method based upon the above testing system.

### BACKGROUND

1. Technical Field

The present disclosure relates to a system and method for testing a DC-to-DC buck converter circuit.

2. Description of Related Art

A computer includes a motherboard and a power supply unit (PSU) connected to the motherboard. The motherboard includes a DC-to-DC buck converter circuit and a CPU connected to the DC-to-DC buck converter circuit. The DC-to-DC buck converter circuit converts an input voltage (e.g., 3.3V) supplied by the PSU to a lower output voltage (e.g., 1.2V) and supplies the lower output voltage to the CPU. To test the DC-to-DC buck converter circuit, a multi-meter and an oscilloscope are used to measure input and output voltages of the DC-to-DC buck converter circuit. A tester determines whether the DC-to-DC buck converter circuit works normally. However, the multi-meter and the oscilloscope have to be adjusted by an operator, which is inconvenient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a DC-to-DC buck converter circuit testing system.

FIG. 2 is a detailed block diagram of a control device of FIG. 1.

FIG. 3 is a flow chart of an embodiment of a DC-to-DC buck converter circuit testing method.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean “at least one.”

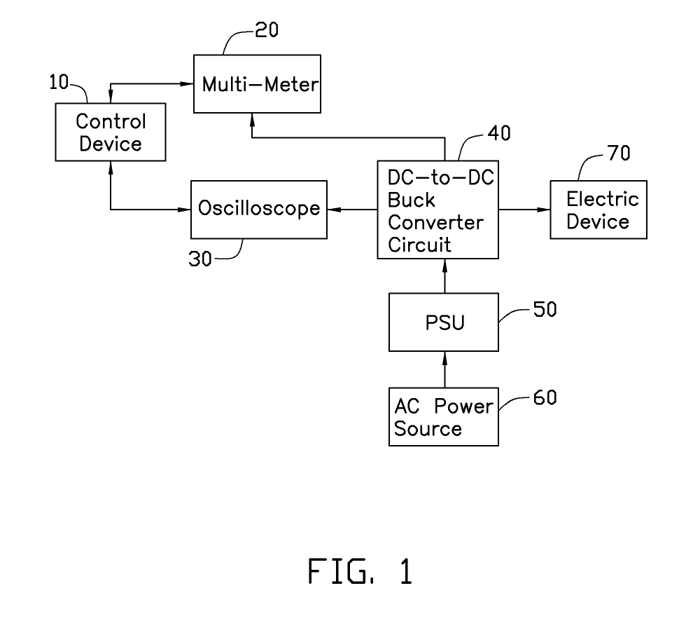

FIG. 1 shows an embodiment of a testing system. The testing system includes a control device 10, a multi-meter 20, an oscilloscope 30, a DC-to-DC buck converter circuit 40, a PSU 50, an alternating current (AC) power source 60, and an electric load 70. The AC power source 60 is connected to the PSU 50 and supplies an AC voltage signal to the PSU 50. The PSU 50 converts the AC voltage signal to a plurality of DC voltages (e.g., 12V, 5V, 3V, etc.). The DC-to-DC buck converter circuit 40 is connected to the PSU 50 and converts one of the DC voltages output by the PSU 50 to a lower DC output voltage which is supplied to the electric load 70. The multi-meter 20 and the oscilloscope 30 are connected to the DC-to-DC buck converter circuit 40. The multi-meter 20 is used for measuring input and output voltages of the DC-to-DC buck converter circuit 40. The oscilloscope 30 is used for detecting waves of the input and output voltage signals of the DC-to-DC buck converter circuit 40. The control device 10 is connected to the multi-meter 20 and the oscilloscope 30 for receiving the voltages and the waves measured by the multi-meter 20 and the oscilloscope 30. The control device 10 analyzes the measured voltages and the waves and generates a test result.

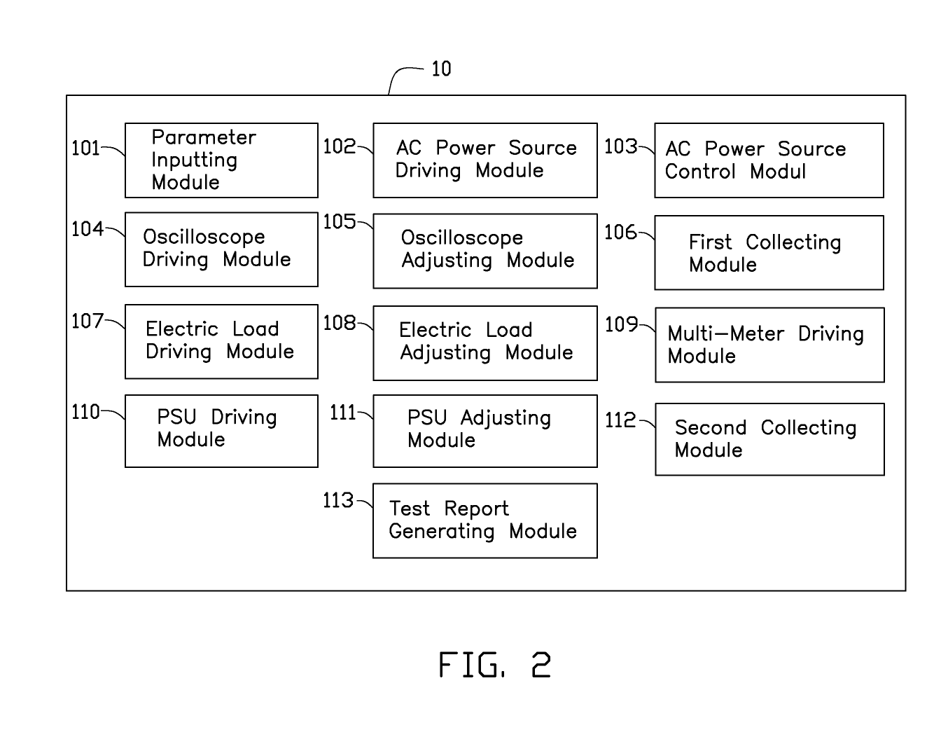

FIG. 2 shows the control device 10 includes a parameter input interface 101, an AC power source driving module 102, an AC power source control module 103, an oscilloscope driving module 104, an oscilloscope adjusting module 105, a first collecting module 106 for receiving waves detected by the oscilloscope 30, an electric load driving module 107, an electric load adjusting module 108, a multi-meter driving module 109, a PSU driving module 110, a PSU adjusting module 111, a second collecting module 112 for receiving the voltages measured by the multi-meter 20, and a test report generating module 113.

The parameter inputting interface 101 allows users to input test parameters. The control device 10 controls the multi-meter 20, the oscilloscope 30, the AC power source 60, the PSU 50, the DC-to-DC buck converter circuit 40, and the electric load 70 according to the test parameters. The AC power source driving module 102 is used for driving the AC power source 60. The oscilloscope driving module 104 is used for driving the oscilloscope 30. The electric load driving module 107 is used for driving the electric load 70. The multi-meter driving module 109 is used for driving the multi-meter 20. The PSU driving module 110 is used for driving the PSU 50. The oscilloscope adjusting module 105 is used for adjusting the oscilloscope 30. The electric load adjusting module 108 is used for adjusting a resistance of the electric load 70. The PSU adjusting module 111 is used for controlling an output voltage of the PSU 50. The test report generating module 113 analyzes the waves detected by the oscilloscope 30 and the voltages measured by the multi-meter 20 generating a test report.

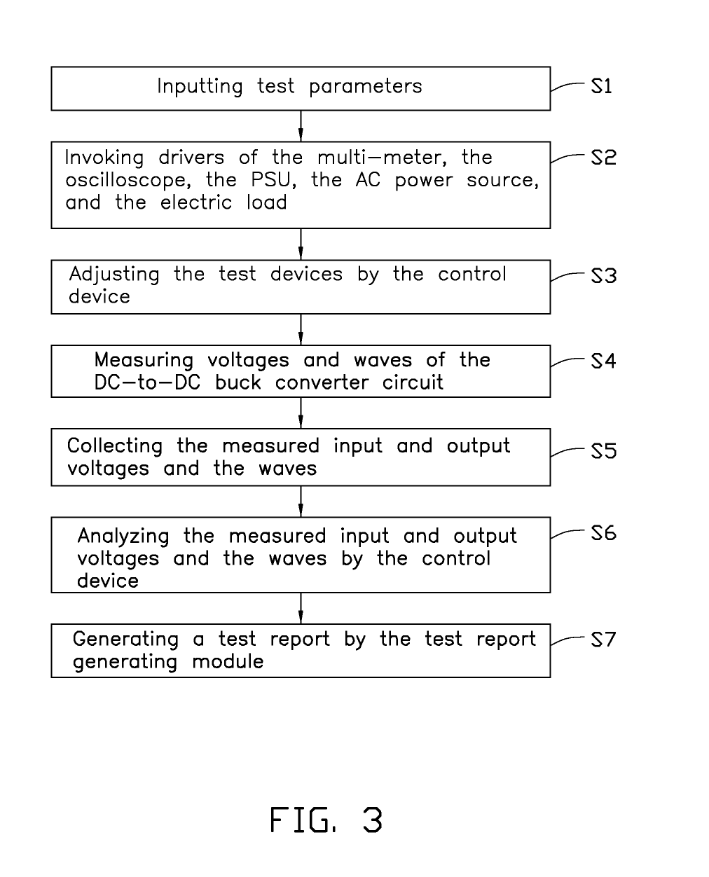

FIG. 3 shows a flow chart of an embodiment of a testing method based upon the above DC-to-DC buck converter circuit testing system. The testing method includes following blocks.

In block S1, test parameters are input through the parameter inputting interface 101. The test parameters are used for adjusting the output voltage of the PSU 50, the resistance of the electric load 70, a location of a center point of the oscilloscope 30, a minimum voltage unit of the oscilloscope 30, and etc.

In block S2, the control device 10 invokes drivers of the multi-meter 20, the oscilloscope 30, the PSU 50, the AC power source 60, and the electric load 70 and controls the multi-meter 20, the oscilloscope 30, the PSU 50, the AC power source 60, and the electric load 70.

In block S3, the control device 10 adjusts the test devices. In this block, the AC power source control module 103 switches on the AC power source 60. The PSU adjusting module 111 adjusts the output voltage of the PSU 50 according to the test parameters. The oscilloscope adjusting module 105 adjusts the location of a center point and the minimum voltage unit of the oscilloscope 30 according to the test parameters. The electric load adjusting module 108 adjusts the resistance of the electric load 70 according to the test parameters.

In block S4, the multi-meter 20 measures input and output voltages of the DC-to-DC buck converter circuit 40 for detecting a converting efficiency of the DC-to-DC buck converter circuit 40; and the oscilloscope 30 measures waves of the input and output voltages of the DC-to-DC buck converter circuit 40 for detecting ripples, distortion of the input and output voltages.

In block S5, the first collecting module 106 collects the waves measured by the oscilloscope 30; and the second collecting module 112 collects the input and output voltages measured by the multi-meter 20.

In block S6, the control device 10 analyzes the measured input and output voltages and the waves. In this block, the control device 10 calculates a ratio of the output voltage and the input voltage of the DC-to-DC buck converter circuit 40 and determines whether the ripples and distortion of the measured wave is within a tolerable range. The tolerable range can be set arbitrarily.

In block S7, the test report generating module 113 generates a test report which shows the ratio of the output voltage and the input voltage of the DC-to-DC buck converter circuit 40 and whether the ripples and distortion of the measured wave is within the tolerable range.

While the present disclosure has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A testing system for a DC-to-DC buck converter circuit, comprising:
a multi-meter connected to the DC-to-DC buck converter circuit for measuring input and output voltages of the DC-to-DC buck converter circuit;
an oscilloscope connected to the DC-to-DC buck converter circuit for measuring waves of the input and output voltages; and
a control device connected to the multi-meter and the oscilloscope; wherein the control device is capable of adjusting the multi-meter and the oscilloscope and gathering data and waves measured by the multi-meter and the oscilloscope; and the control device comprises a test report generating module capable of generating a test report according to the data and waves measured by the multi-meter and the oscilloscope.

2. The testing system of claim 1, further comprising a PSU connected to the DC-to-DC buck converter circuit for providing the input voltage to the DC-to-DC buck converter circuit, an AC power source connected to the power supply unit (PSU) for supplying an AC power source to the PSU, and an electric load connected to the DC-to-DC buck converter circuit for receiving the output voltage of the DC-to-DC buck converter circuit.

3. The testing system of claim 2, wherein the control device further comprises an AC power source driving module for driving the AC power source, an oscilloscope driving module for driving the oscilloscope, an electric load driving module for driving the electric load, a multi-meter driving module for driving the multi-meter, and a PSU driving module for driving the PSU.

4. The testing system of claim 3, wherein the control device further comprises an oscilloscope adjusting module, configured for adjusting a location of a center point and a minimum voltage unit of the oscilloscope, and a first collecting module, configured for receiving the waves detected by the oscilloscope.

5. The testing system of claim 3, wherein the control device further comprises an electric load adjusting module, configured for adjusting a resistance of the electric load, and a PSU adjusting module, configured for adjusting an output voltage of the PSU.

6. The testing system of claim 3, wherein the control device further comprises a parameter inputting interface for inputting test parameters, and the test parameters are configured for adjusting the output voltage of the PSU, the resistance of the electric load, the location of the center point and the minimum voltage unit of the oscilloscope.

7. A testing method for a DC-to-DC buck converter circuit, comprising following steps:
providing a multi-meter, an oscilloscope, and a control device connected to the multi-meter and the oscilloscope;
adjusting the multi-meter and the oscilloscope by the control device;
measuring input and output voltages of the DC-to-DC buck converter circuit by the multi-meter and measuring waves of the input and output voltages by the oscilloscope;
reading the measured input and output voltages and the waves by the control device;
analyzing the measured input and output voltages and the waves by the control device; and
generating a test report according to the analyzing result.

8. The testing method of claim 7, wherein the step of analyzing comprises calculating a ratio of the output voltage and the input voltage of the DC-to-DC buck converter circuit and determining whether ripples and distortion of the measured waves are within a tolerable range.

9. The testing method of claim 8, further comprising providing a PSU for supplying the input voltage of the DC-to-DC buck converter circuit and connecting an electric load to an output terminal of the DC-to-DC buck converter circuit.

10. The testing method of claim 9, further comprising inputting test parameters through the control device, wherein the test parameters are configured for adjusting the input voltage supplied by the PSU, the resistance of the electric load, a location of a center point of the oscilloscope, and a minimum voltage unit of the oscilloscope.
